(19) United States
(12) Patent Application Publication
(10) Pub. No.: US 2012/0235542 A1
(43) Pub. Date: Sep. 20, 2012

(54) PIEZOELECTRIC DEVICE

(75) Inventor: Takehiro TAKAHASHI, Saitama (JP)

(73) Assignee: NIHON DEMPA KOGYO CO., LTD., TOKYO (JP)

(21) Appl. No.: 13/411,714

(22) Filed: Mar. 5, 2012

(30) Foreign Application Priority Data
Mar. 15, 2011 (JP) JP2011-056626
Feb. 24, 2012 (JP) JP2012-038875

(51) Int. Cl. H01L 41/053; H05K 7/02

(52) U.S. Cl. 310/344; 361/808

(57) ABSTRACT

To facilitate positioning of an external terminal and ensure sufficient solder joint strength at the time of mounting a piezoelectric device on a mounting board by soldering. In a crystal device of the present invention, an external terminal is formed, for example, at four corners on an external bottom surface of a base having a rectangular shape as seen in a plan view, and the external terminals include two active terminals arranged opposite to each other on a diagonal line, and two ground terminals arranged opposite to each other on another diagonal line crossing the diagonal line. An arbitrary sign, character, or figure is marked on a mounting surface of at least one ground terminal of external terminals to determine the direction of the active terminal.

### TECHNICAL FIELD

The present invention relates to a piezoelectric device such as a crystal resonator or a crystal oscillator using a piezoelectric material, and more specifically, relates to a piezoelectric device that facilitates positioning of an external terminal and ensures joint strength, at the time of mounting the piezoelectric device on a mounting board by soldering.

### BACKGROUND ART

A piezoelectric device such as a crystal resonator and a crystal oscillator is small and lightweight, and hence it is incorporated into portable electronic devices, for example, cell phones, where it is used as a reference source of frequency and time.

A crystal resonator in a conventional example as shown in FIGS. 3(a) and 3(b), is formed by mounting a crystal blank (not shown) on a surface of a base 2 having a rectangular shape as seen in a plan view, and placing a metal cover 3 with type name, frequency, order specification number, and the like of the crystal resonator printed on an external surface thereof, on the base 2, and seam welding to the base 2 to effect hermetically sealing. Two castellations 4a and 4b provided with a measurement terminal are formed on opposite sides of short sides of the base 2, and side terminal electrodes 5a, 5b, 5c, and 5d are formed at four corners of the base 2. Four external terminals 6a, 6b, 6c, and 6d having a rectangular shape as seen in a plan view and electrically connected to the side terminal electrodes 5a, 5b, 5c, and 5d, are formed at four corners on an external bottom surface (foot forming surface) 2a of the base 2.

These four external terminals 6a, 6b, 6c, and 6d are set as two active terminals (HOT terminals) 6b and 6d and remaining two ground terminals (GND terminals), and for example, as shown in FIG. 3(c), in one ground terminal 6a, one end of a short side of the rectangle is cut to form a so-called C surface. Moreover, for example, the two active terminals (HOT terminals) 6b and 6d are formed on a diagonal line with respect to the C surface. Consequently, at the time of mounting the crystal resonator on the mounting board, positioning is performed by using the C surface as a reference, and a worker recognizes the direction of the active terminal of the crystal resonator, and bonds the crystal resonator to the mounting board by soldering.

### PRIOR ART DOCUMENT

[Patent Document 1] Japanese Unexamined Patent Publication No. 2004-354198

### SUMMARY OF THE INVENTION

### Problems to be Solved by the Invention

As miniaturization and low height of the crystal devices progress, the area of the foot (mounting terminal) pattern becomes smaller and smaller. With a decrease in the area of the foot pattern, customer requests with respect to solder printing accuracy and accuracy of the mounting position at the time of mounting the crystal resonator on the mounting board become more difficult to meet.

However, in this type of crystal resonator in the conventional example, as shown in FIG. 3(c), the C surface is formed in, for example, one of the four mounting terminals, for example, in the mounting terminal 6a. Therefore, the surface area of the mounting terminal 6a decreases. Consequently, other mounting terminals 6b, 6c, and 6d formed at the corners of the base are not well balanced, the soldering area decreases, and the flow of solder becomes non-uniform, thereby decreasing the joint strength to the mounting board by soldering. Moreover, for example, when the crystal device is mounted on a cell phone, at the time of pressing an operation button, the pressing force is dispersed and not applied uniformly to the mounting board, thereby deforming the mounting board and generating a stress. Accordingly, properties such as frequency and crystal impedance fluctuate largely, and the mounting board may be damaged due to stress concentration.

### Means for Solving the Problems

In order to solve the aforementioned problems, in a crystal device of the present invention, instead of forming the C surface on the mounting terminal, an arbitrary sign, character, figure, or the like is marked on the mounting surface of the external terminal formed on the foot pattern forming surface.

Accordingly, in the piezoelectric device of the present invention, an external terminal is formed on an external bottom surface of the base having a substantially rectangular shape as seen in a plan view, and an arbitrary sign, character, figure, or the like is marked on the mounting surface of the external terminal, so that a worker or a mounting device can easily determine the direction of the active terminal.

Moreover, in the present invention, marking is performed at the center on the mounting surface of the external terminal.

Furthermore, in the present invention, a thin film is formed on the mounting surface of the external terminal, and marking is performed by printing on the thin film at the center on the mounting surface.

In the present invention, further, a thin film is formed on the mounting surface of the external terminal, and marking is performed by etching on the thin film at the center on the mounting surface, to penetrate through the thin film.

Moreover, in the present invention, a thin film having a normal thickness is formed on the mounting surface of the external terminal, which is not marked, and a thin film having a film thickness thinner than that of the thin film having the normal thickness is formed on the mounting surface of the external terminal to be marked.

Furthermore, in the present invention, a thin film having a normal thickness is formed on the mounting surface of the external terminal, and a center of the mounting surface of the external terminal to be marked is partly chemically engraved to form a thin film thinner than the thin film having the normal thickness, to perform marking.

Moreover, in the present invention, the marking is formed by printing, laser machining, or etching simultaneously at the time of patterning the mounting terminal on the principal surface of the wafer at a wafer level.

Furthermore, in the present invention, the piezoelectric device is a crystal resonator or a crystal oscillator including a ceramic base and a metal cover.

Moreover, in the present invention, the piezoelectric device is a crystal resonator or a crystal oscillator formed by joining a crystal plate (substrate) formed with a crystal blank to the base made of ceramic, a crystal plate, or glass, and joining a lid made of a crystal plate or glass to an upper surface of the crystal plate.

### Effects of the Invention

According to the present invention, positioning of an external terminal at the time of mounting a piezoelectric device to a mounting board is facilitated, and joint strength can be ensured by soldering.

### BRIEF DESCRIPTION OF THE DRAWINGS

FIG. 1 is a bottom view (foot pattern forming surface) of a package (base) of a crystal device in an embodiment of the present invention.

FIG. 2 is an enlarged sectional view on arrow II-II of a mounting terminal of the crystal device, in the embodiment of the present invention shown in FIG. 1. FIG. 2(a) shows an embodiment in which a mark such as a character is marked on the surface of a gold foil formed on a mounting surface of the mounting terminal. FIG. 2(b) shows an embodiment in which the surface of the gold foil is laser machined or etched to chemically engrave a character or the like, to thereby perform marking. FIG. 2(c) shows an embodiment in which the thickness of gold foil plated on the mounting surface of the external terminal to be marked is made thinner than other mounting terminals. FIG. 2(d) shows an embodiment in which a center of the mounting surface of the external terminal to be marked is partially chemically engraved so that a thin film thinner than a thin film having a normal thickness is formed and marked.

FIG. 3 shows a package of a crystal device in a conventional example, wherein FIG. 3(a) is a plan view thereof, FIG. 3(b) is a side view thereof, and FIG. 3(c) is a bottom view (foot pattern forming surface) thereof.

### BEST MODE FOR CARRYING OUT THE INVENTION

Hereunder, an embodiment of the present invention in which a piezoelectric device of the present invention is applied to a crystal device will be explained with reference to the accompanying drawings.

### Embodiment

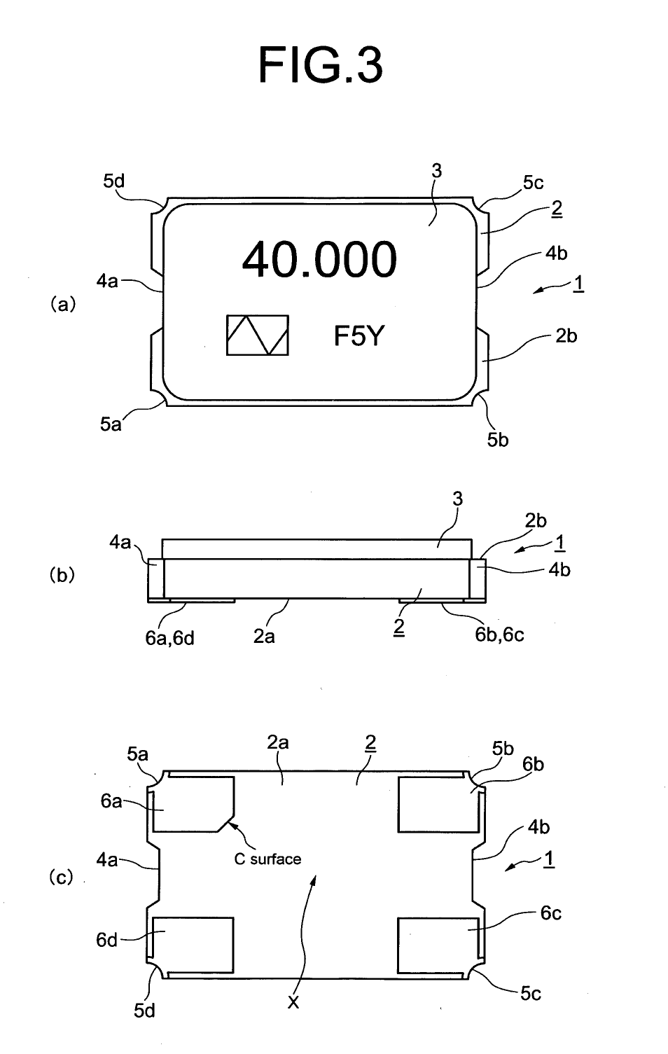

A crystal device, for example, a crystal resonator 1 in the embodiment of the present invention is formed, as in the crystal resonator 1 in the conventional example shown in FIG. 3(a) and FIG. 3(b), by mounting a crystal blank (not shown) on a surface of a base 2 having a rectangular shape as seen in a plan view, and placing a metal cover 3 on the base 2 and seam welding to the base 2, to effect hermetic sealing. Two castellations 4a and 4b provided with a measurement terminal are formed on opposite sides of short sides of the base 2, and side terminal electrodes 5a, 5b, 5c, and 5d are respectively formed at four corners of the base 2. Four external terminals 6a, 6b, 6c, and 6d having a rectangular shape as seen in a plan view and electrically connected to the side terminal electrodes 5a, 5b, 5c, and 5d, are formed at four corners on an external bottom surface (foot forming surface) 2a of the base 2.

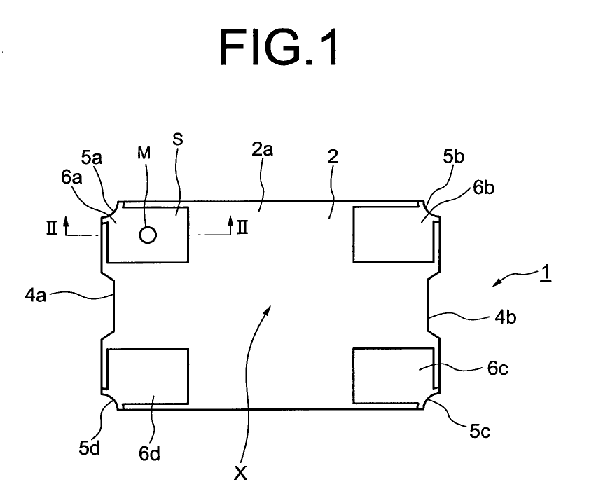

As shown in FIG. 1, the four external terminals 6a, 6b, 6c, and 6d are set, for example, as two active terminals (HOT terminals) 6b and 6d arranged opposite to each other on a diagonal line, and remaining two ground terminals (GND terminals) 6a and 6c arranged opposite to each other on another diagonal line crossing the diagonal line.

Moreover, for example instead of forming the C surface on the ground terminal 6a in the conventional example shown in FIG. 3(c), as shown in FIG. 1, an arbitrary sign, character, or figure M is marked at the center of a mounting surface S of the ground terminal 6a, and the crystal resonator 1 is mounted on a mounting board (not shown) and soldered so that the two active terminals (HOT terminals) are positioned opposite to each other on the diagonal line as seen from the center of the marked ground terminal 6a.

Moreover, in the present invention, marking is performed not only on the ground terminal, but may be performed on the active terminal.

By performing marking at the center on the mounting surface S of the mounting terminals 6a to 6d, then at the time of mounting the crystal device on the mounting board, molten solder for mounting uniformly flows from the periphery of the mounting surface S toward the center thereof so that the mark M is completely covered with the molten solder and a strong and reliable joint strength with the mounting board can be ensured.

The sign, character, or figure M to be marked can have any shape, such as a circle, a triangle, or a square. However, in the present embodiment, a dot or the like, which is a relatively simple shape, is printed at the center of one connection terminal 6a, or is formed simultaneously when the mounting terminal is patterned at a wafer level by laser machining, etching, or the like, and is cut into individual pieces to form the crystal resonator 1. By forming the marking on one connection terminal 6a, the direction of the mounting terminal (active terminal) can be efficiently determined by the worker or the mounting device by just one visual observation.

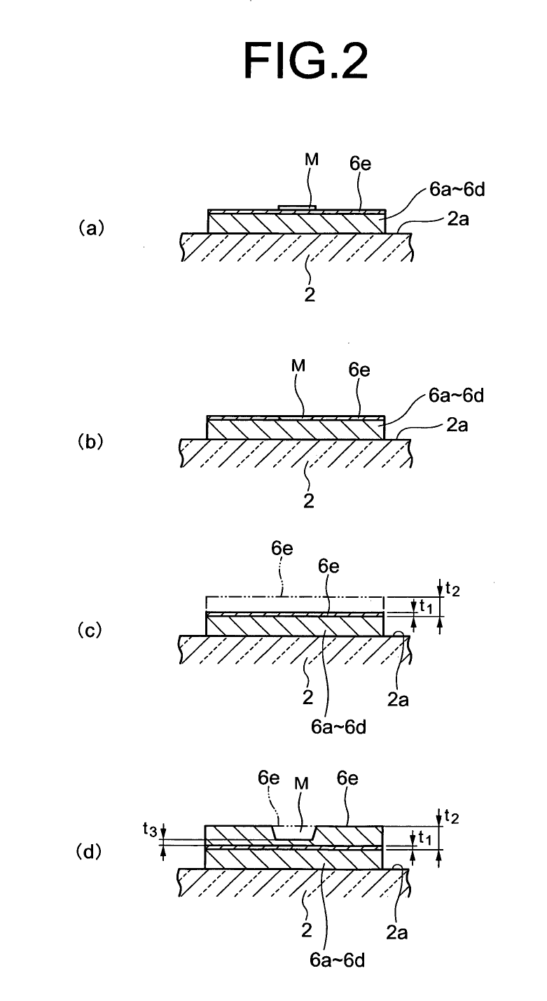

Here, a marking method with respect to the mounting terminal in the embodiment of the crystal device of the present invention will be explained in detail with reference to FIG. 2.

As shown in FIG. 2(a), the mounting terminals 6a to 6d made of, for example, tungsten or nickel are formed on the external bottom face 2a of the base 2 of the crystal device at the wafer level, and a thin film 6e made of, for example, gold is formed by printing or the like on upper surfaces of these mounting terminals 6a to 6d for facilitating soldering at the time of mounting. Mark M formed of an arbitrarily sign, character, or figure is marked on an upper surface of the thin film 6e by printing or the like. Here, as a material of the mark M, a material having low electrical resistance and excellent wettability of the solder is desired. For example, Cr, Ni, W, Pd, or the like can be used.

As shown in FIG. 2(b), the thin film 6e made for example of gold, is formed by printing or the like on the upper surfaces of the mounting terminals 6a to 6d made of tungsten or nickel formed on the external bottom surface 2a of the base 2 of the crystal device, the surface of the thin film 6e is chemically engraved by laser machining or etching to form a depression part, and this depression part is used as the mark M described above. Here, the upper surfaces of the mounting terminals 6a to 6d made of tungsten or nickel can be chemically engraved, to penetrate through the thin film 6e, or a part of the mounting terminals 6a to 6d can be chemically engraved to perform marking.

Moreover, as shown in FIG. 2(c), the thin film 6e made for example of gold, is formed on the upper surfaces of the mounting terminals 6a to 6d made of tungsten or nickel formed on the external bottom surface 2a of the base 2 of the crystal device. However, at this time, a thin film made for example of gold, having a thickness t₂ of, for example, 2000 A° to 4000 A° as in the normal thin film is formed on the upper surface of the mounting terminal not to be marked, and a thin film 6e made for example of gold, having a thickness t₁ of, for example, 500 A° thinner than the thin film t₂ is formed on the upper surface of the mounting terminal to be used for marking. Due to a difference in thickness t₂-t₁ (shown as light and shade) of the thin films 6e, when light is irradiated from an optical apparatus onto the thin film 6e formed on the surface of the mounting terminal, in the case where the thin film 6e is thick, due to the difference in thickness t₂-t₁ of these thin films 6e, only the gold thin film 6e reflects and the gold surface is detected. On the other hand, in the mounting terminal formed with the thin film 6e, a surface of dark brown color made of tungsten or nickel formed under the thin film 6e is seen through and detected. Marking is performed due to a difference (contrasting density) in reflected light on the upper surface of the mounting terminal, and the active terminal is identified. Furthermore, as shown in FIG. 2(d), the center of the thin film 6e (t₂) can be partly shaved off to form a thin film having a thickness t₃ to form a depression with a bottom, which can be used as the mark M.

Moreover, a cross area X formed between the respective mounting terminals on the foot pattern forming face (external bottom surface) 2a can be marked. However, due to miniaturization of the crystal resonator, the area becomes increasingly narrow. Consequently, it is desired to mark the sign or character M at the center on the mounting surface S of the mounting terminal that can ensure a relatively wide area.

The material of the mounting terminals 6a, 6b, 6c, and 6d formed by plating, printing, or the like on the external bottom surface 2a of the crystal resonator 1 is generally gold, tungsten, or nickel. Gold has extremely good wettability with respect to solder, but the cost is high. Therefore, tungsten or nickel is frequently used for the mounting terminal.

The crystal device in the embodiment of the present invention is used for a crystal resonator, a crystal oscillator, and the like having four terminals and six terminals. The crystal device is also used for a crystal resonator having a double-layered structure including a ceramic base and a metal cover in a conventional structure, and a crystal resonator and a crystal oscillator having a three-layered structure in which a crystal plate formed with a crystal blank is joined on a base made of a crystal plate or glass, and a lid made of a crystal plate or glass is joined on an upper surface of the crystal plate. In the crystal resonator having two terminals, marking is not required because the two terminals are used as the active terminal.

In the embodiment of the present invention, the crystal device having a crystal blank mounted on a base is explained. However, the present invention can be applied to a piezoelectric device mounted with a vibrating reed made of a piezoelectric material such as lithium tantalite, lithium niobate, or piezoelectric ceramic, other than the crystal blank.

What is claimed is:

1. A piezoelectric device in which an external terminal is formed on an external bottom surface of a base having a rectangular shape as seen in a plan view, wherein an arbitrary sign, character, or figure is marked on a mounting surface of said external terminal to determine a direction of an active terminal.

2. A piezoelectric device according to claim 1, wherein marking is performed at the center of said mounting surface of said external terminal.

3. A piezoelectric device according to claim 1, wherein a thin film is formed on said mounting surface of said external terminal, and marking is performed by printing at the center of said thin film formed on said mounting surface.

4. A piezoelectric device according to claim 1, wherein a thin film is formed on said mounting surface of said external terminal, and marking is performed by etching at the center of said thin film formed on said mounting surface, to penetrate through said thin film.

5. A piezoelectric device according to claim 1, wherein a thin film having a normal thickness is formed on said mounting surface of said external terminal, which is not marked, and a thin film having a film thickness thinner than that of said thin film having the normal thickness is formed on said mounting surface of said external terminal to be marked.

6. A piezoelectric device according to claim 1, wherein a thin film having a normal thickness is formed on said mounting surface of said external terminal, and a center of said mounting surface of said external terminal to be marked is partly chemically engraved to form a thin film thinner than the thin film having the normal thickness, to perform marking.

7. A piezoelectric device according to claim 1, wherein said marking is formed by printing, laser machining, or etching simultaneously at the time of patterning said mounting terminal at a wafer level.

8. A piezoelectric device according to claim 1, wherein said piezoelectric device is a crystal resonator or a crystal oscillator including a ceramic base and a metal cover.

9. A piezoelectric device according to claim 1, wherein said piezoelectric device is a crystal resonator or a crystal oscillator formed by joining a crystal plate formed with a crystal blank to said base made of ceramic, a crystal plate, or glass, and joining a lid made of a crystal plate or glass to an upper surface of said crystal plate.
